(19) United States
(12) Patent Application Publication
(10) Pub. No.: US 2026/0011690 A1
(43) Pub. Date: Jan. 8, 2026

(54) INTEGRATED CIRCUIT DEVICE AND ADAPTIVE POWER SCALING METHOD THEREOF

(71) Applicants: Global Unichip Corporation, Hsinchu (TW); Taiwan Semiconductor Manufacturing Company, Ltd., Hsinchu (TW)

(72) Inventors: Shih-Hsuan Hsu, Hsinchu (TW); Shen-Pai Lin, Hsinchu (TW); Igor Elkanovich, Hsinchu (TW); Yung-Sheng Fang, Hsinchu (TW)

(73) Assignees: Global Unichip Corporation, Hsinchu (TW); Taiwan Semiconductor Manufacturing Company, Ltd., Hsinchu (TW)

(21) Appl. No.: 18/764,174

(22) Filed: Jul. 4, 2024

(51) Int. Cl. H01L 25/065; H01L 23/00

(52) U.S. Cl. CPC H01L 25/0657; H01L 24/08; H01L 24/16; H01L 24/32; H01L 24/73; H01L 2224/08146; H01L 2224/16145; H01L 2224/32145; H01L 2224/73204; H01L 2225/06513; H01L 2225/06541; H01L 2924/14252; H01L 2924/1427; H01L 2924/1431

(57) ABSTRACT

The invention provides an integrated circuit device and an adaptive power scaling method thereof to reduce and optimize power consumption. The integrated circuit device includes a first die and a second die, wherein the first die and the second die are stacked into a three-dimensional structure. A power circuit provides a power voltage to a first interface circuit of the first die and a second interface circuit of the second die. The first interface circuit transmits data to the second interface circuit via a die-to-die transfer circuit. The control logic controls the power circuit to adjust the power voltage provided to the first interface circuit and the second interface circuit based on the signal quality of the data received by the second interface circuit.

### BACKGROUND OF THE INVENTION

### Field of the Invention

The invention relates to an electronic circuit, and in particular to an integrated circuit device and an adaptive power scaling method thereof.

### Description of Related Art

Universal Chiplet Interconnect Express (UCIe) is an open specification for die-to-die interconnects and serial buses between chiplets. Power efficiency is one of many important issues when it comes to die-to-die interconnect design.

### SUMMARY OF THE INVENTION

The invention provides an integrated circuit device and an adaptive power scaling method thereof to reduce and optimize power consumption.

In an embodiment of the invention, an integrated circuit device includes a first die and a second die, wherein the first die and the second die are stacked into a three-dimensional structure. The integrated circuit device also includes a power circuit and a control logic. The power circuit provides a power voltage to a first interface circuit of the first die and a second interface circuit of the second die. The first interface circuit transmits data to the second interface circuit via a die-to-die transfer circuit in the integrated circuit device. The second die reports an signal quality of the received data to the control logic. The control logic is coupled to the power circuit. The control logic controls the power circuit to adjust the power voltage provided to the first interface circuit and the second interface circuit based on the signal quality of the data received by the second interface circuit.

In an embodiment of the invention, an adaptive power scaling method includes: providing a power voltage to a first interface circuit of a first die and a second interface circuit of a second die via a power circuit of an integrated circuit device, wherein the first interface circuit transmits data to the second interface circuit via a die-to-die transfer circuit of the integrated circuit device; reporting an signal quality of the received data to a control logic of the integrated circuit device via the second die; and controlling the power circuit via the control logic to adjust the power voltage provided to the first interface circuit and the second interface circuit based on the signal quality of the data received by the second interface circuit.

Based on the above, the integrated circuit device of the embodiments of the invention may be applied to high-speed die-to-die (D2D) interconnect design. The first interface circuit of the first die transmits data to the second interface circuit of the second die via the die-to-die transfer circuit, and then the second die reports the signal quality of the received data to the control logic. Therefore, the control logic may adjust the power voltage provided to the first interface circuit and the second interface circuit based on the signal quality of the data received by the second interface circuit, so as to reduce and optimize the power consumption of the integrated circuit device.

In order to make the aforementioned features and advantages of the disclosure more comprehensible, embodiments accompanied with figures are described in detail below.

### BRIEF DESCRIPTION OF THE DRAWINGS

FIG. 1A is a schematic cross-sectional view of a three-dimensional structure of an integrated circuit device shown according to an embodiment.

FIG. 1B is a schematic cross-sectional view of a three-dimensional structure of an integrated circuit device shown according to another embodiment.

FIG. 2 is a schematic circuit block diagram of an integrated circuit device according to an embodiment of the invention.

FIG. 3 is a schematic flowchart of an adaptive power scaling method of an integrated circuit device according to an embodiment of the invention.

FIG. 4 is a schematic circuit block diagram of a die shown according to an embodiment of the invention.

FIG. 5 is a schematic flowchart of an adaptive power scaling method according to another embodiment of the invention.

FIG. 6 is a schematic flowchart of an adaptive power scaling method according to another embodiment of the invention.

### DESCRIPTION OF THE EMBODIMENTS

The term “coupled to (or connected to)” used in the entire text of the specification of the present application (including claims) may refer to any direct or indirect connecting means. For example, if it is herein described that a first device is coupled (or connected) to a second device, it should be interpreted that the first device may be directly connected to the second device, or the first device may be indirectly connected to the second device via other devices or some connection means. Terms such as “first” and “second” mentioned throughout the specification (including the claims) of the present application are used to name elements or to distinguish between different embodiments or scopes, and are not used to limit the upper bound or the lower bound of the number of elements, nor used to limit the sequence of elements. In addition, wherever possible, elements/members/steps using the same reference numerals in the drawings and embodiments denote the same or similar parts. Cross-reference may be made to relevant descriptions of elements/members/steps using the same reference numerals or using the same terms in different embodiments.

The invention relates to data transmission between two dies. The dies are also called chiplets. Several embodiments are provided below to introduce the invention, but the implementation of the invention is not limited to the embodiments.

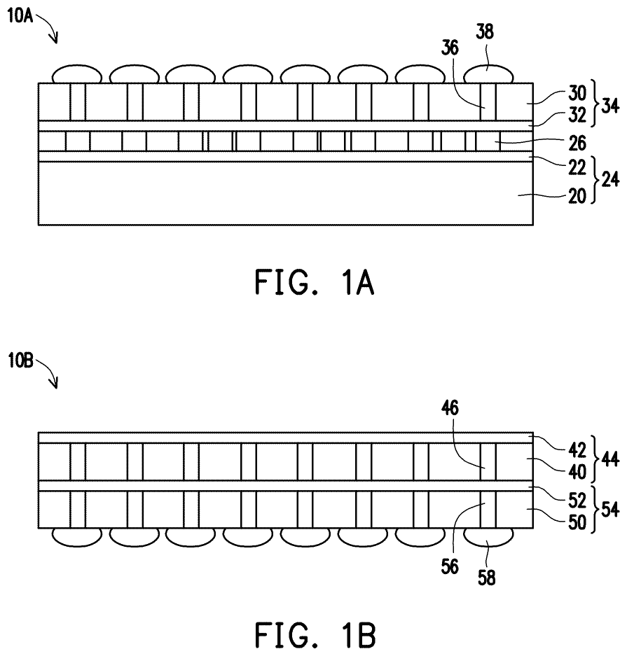

FIG. 1A is a schematic cross-sectional view of a three-dimensional structure of an integrated circuit device 10A shown according to an embodiment. The integrated circuit device 10A may include a die 24 and a die 34. In addition to being horizontally distributed, the die 24 and the die 34 may also be stacked vertically. For example, the die 24 and the die 34 are electrically connected to each other and stacked into a three-dimensional structure to form a three-dimensional semiconductor element. The stacked structure of the integrated circuit device 10A may adopt any three-dimensional packaging technique, such as system-on-integrated-chips (SoIC) packaging, wafer-on-wafer (WoW) packaging, chip-on-wafer-on-substrate (CoWoS) packaging, or other three-dimensional packaging techniques.

In some practical applications (but not limited thereto), the die 34 may be a slave device, and the die 24 may be a master device. The die 24 typically includes a substrate 20 and a circuit layer 22. The die 34 is stacked above the die 24. At least one bump 26 (e.g., micro bump or hybrid bump) is formed between the die 24 and the die 34. The die 34 includes a substrate 30 and a circuit layer 32. The through-hole structure of the packaging process, such as a through-silicon-via (TSV) 36 having a connection pad portion 38, is formed at a corresponding position of the die 34. The connection pad portion 38 is formed at the outermost surface corresponding to the TSV 36.

FIG. 1B is a schematic cross-sectional view of a three-dimensional structure of an integrated circuit device 10B shown according to another embodiment. The integrated circuit device 10B may include a die 44 and a die 54. In addition to being horizontally distributed, the die 44 and the die 54 may also be stacked vertically. For example, the die 44 and the die 54 are electrically connected to each other and stacked into a three-dimensional structure to form a three-dimensional semiconductor element. The stacked structure of the integrated circuit device 10B may adopt any three-dimensional packaging technique, such as SoIC packaging, WoW packaging, CoWoS packaging, or other three-dimensional packaging techniques. In some practical applications (but not limited thereto), the die 54 may be a slave device, and the die 44 may be a master device. The die 44 typically includes a substrate 40 and a circuit layer 42. The via structure of the packaging process, such as the TSV 46, is formed between the die 44 and the die 54. The die 54 includes a substrate 50 and a circuit layer 52. A TSV 56 having a connection pad portion 58 is formed at the corresponding position of the die 54. The connection pad portion 58 is formed at the outermost surface corresponding to the TSV 56.

Universal Chiplet Interconnect Express (UCIe) is an open specification for die-to-die interconnects and serial buses between chiplets. Power efficiency is one of many important issues when it comes to die-to-die interconnect design. The following embodiments illustrate the use of an adaptive power scaling (APS) method to find the appropriate power voltage to obtain optimized performance between eye opening and power consumption.

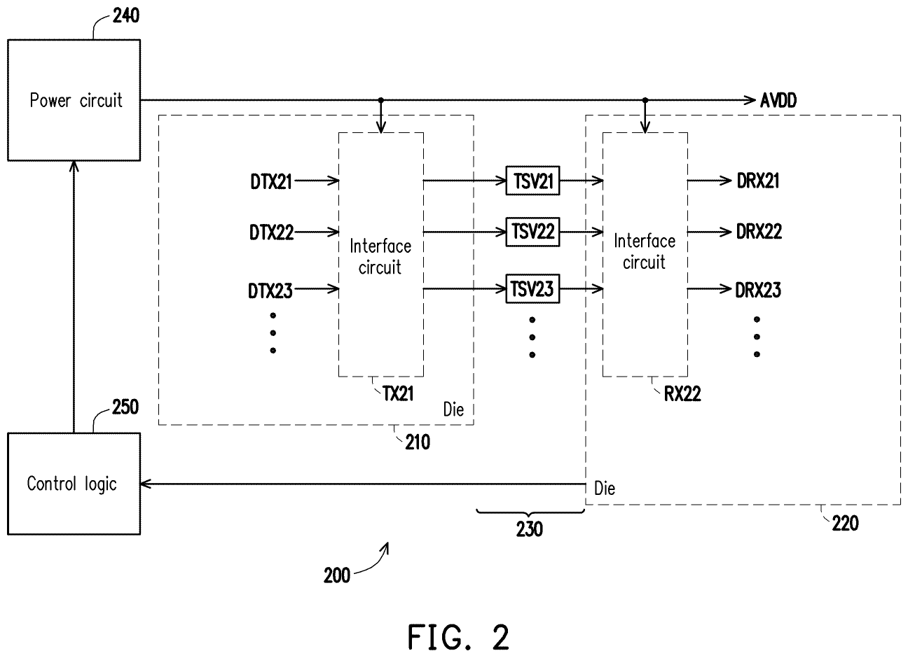

FIG. 2 is a schematic circuit block diagram of an integrated circuit device 200 according to an embodiment of the invention. The integrated circuit device 200 shown in FIG. 2 includes a die 210 and a die 220. The die 210 and the die 220 may be electrically connected to each other. In the embodiment shown in FIG. 2, an interface circuit TX21 of the die 210 transmits data to an interface circuit RX22 of the die 220 via a die-to-die transfer circuit 230 in the integrated circuit device 200. For example, the die 210 may be electrically connected to the die 220 via TSVs (or bumps) TSV21, TSV22, TSV23, . . . , or an interposer circuit. The interface circuit TX21 may transmit data DTX21, DTX22, DTX23, . . . to the interface circuit RX22 via the TSVs (or bumps) TSV21 to TSV23. Therefore, the interface circuit RX22 may receive data DRX21, DRX22, DRX23, . . . from the interface circuit TX21 via the TSVs (or bumps) TSV21 to TSV23. In the initialization period of the integrated circuit device 200, the data DTX21 to DTX23 include a pseudorandom binary sequence (PRBS).

According to the actual design, the die 210 and the die 220 may be stacked into a three-dimensional structure. For example, in some application examples, the die 210 and the die 220 shown in FIG. 2 are as provided in the relevant descriptions of the die 24 and the die 34 shown in FIG. 1A and analogized as such. In this case, the TSVs TSV21 to TSV23 shown in FIG. 2 may be implemented using bumps instead. That is, the TSVs TSV21 to TSV23 shown in FIG. 2 are as provided in the relevant description of the bump 26 shown in FIG. 1A and analogized as such. In some other application examples, the die 210 and the die 220 shown in FIG. 2 are as provided in the relevant descriptions of the die 44 and the die 54 shown in FIG. 1B and analogized as such. In this case, the TSVs TSV21 to TSV23 shown in FIG. 2 are as provided in the relevant description of the TSV 46 shown in FIG. 1B and analogized as such.

In the embodiment shown in FIG. 2, the integrated circuit device 200 further includes a power circuit 240 and a control logic 250. The control logic 250 is coupled to the power circuit 240. In the present embodiment, the control logic 250 may run an adaptive power scaling method to control the power circuit 240 to find an appropriate power voltage AVDD.

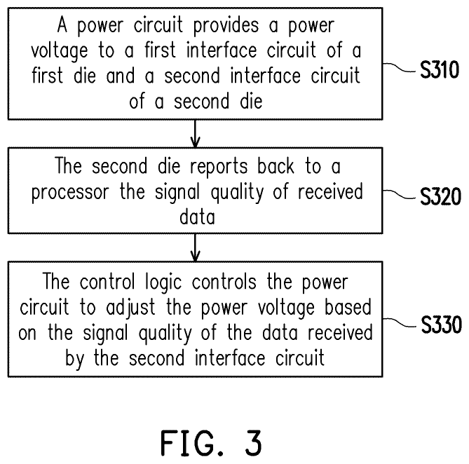

FIG. 3 is a schematic flowchart of an adaptive power scaling method of an integrated circuit device according to an embodiment of the invention. Please refer to FIG. 2 and FIG. 3. In step S310, the power circuit 240 may provide the power voltage AVDD to the interface circuit TX21 of the die 210 (the first interface circuit of the first die) and the interface circuit RX22 of the die 220 (the second interface circuit of the second die). The present embodiment does not limit the specific implementation of the power circuit 240. Depending on the actual design, the power circuit 240 may be a conventional power circuit or other power supply circuits. For example, the power circuit 240 may include a voltage regulator, a DC-to-DC converter, or other DC power supply circuits.

The die 220 may check the signal quality and accuracy of the received data DRX21 to DRX23. For example, the die 220 may use checksum information, error correction code (ECC), or other checking techniques of the data DRX21 to DRX23 to check the accuracy of the data DRX21 to DRX23. For example, the die 220 may also check the signal quality of the data DRX21 to DRX23 from the die 210, and then report the sensing results on the signal quality of the data DRX21 to DRX23 to the control logic 250. Based on practical applications, the signal quality includes at least one of an eye height characteristic and an eye width characteristic of the data DRX21 to DRX23.

In step S320, the die 220 reports the signal quality of the received data DRX21 to DRX23 to the control logic 250. Therefore, the control logic 250 may know at any time whether the data DRX21 to DRX23 received by the die 220 are pass or fail. In step S330, the control logic 250 may control the power circuit 240 according to the information reported by the die 220. Based on the signal quality of the data DRX21 to DRX23 received by the interface circuit RX22, the control logic 250 may adjust (increase or reduce) the power voltage AVDD provided to the interface circuits TX21 and RX22 (step S330). That is, based on the information (the signal quality of the data DRX21 to DRX23 received by the interface circuit RX22) reported by the die 220, the control logic 250 may control the power circuit 240 to adjust the power voltage AVDD to reduce and optimize the power consumption of the integrated circuit device 200.

Based on the above, the integrated circuit device 200 may be applied to high-speed die-to-die (D2D) interconnect design. The interface circuit TX21 of the die 210 transmits the data DTX21 to DTX23 to the interface circuit RX22 of the die 220 via the die-to-die transfer circuit 230, and then the die 220 reports the signal quality of the received data DRX21 to DRX23 to the control logic 250. Therefore, the control logic 250 may adjust the power voltage AVDD provided to the interface circuits TX21 and RX22 to reduce and optimize the power consumption of the integrated circuit device 200 based on the signal quality of the data DRX21 to DRX23 received by the interface circuit RX22.

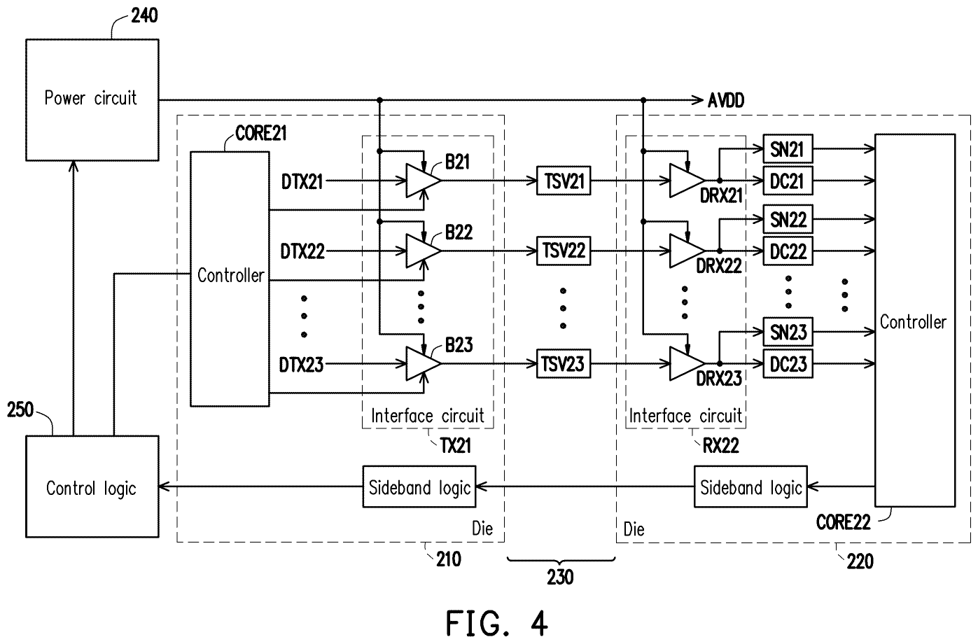

FIG. 4 is a schematic circuit block diagram of the dies 210 and 220 shown according to an embodiment of the invention. The dies 210 and 220 shown in FIG. 4 may be used as one of many implementation examples of the dies 210 and 220 shown in FIG. 2. In the embodiment shown in FIG. 4, the die 210 includes a controller CORE21 and the interface circuit TX21, and the die 220 includes the interface circuit RX22, a data checking circuit (such as DC21, DC22, . . . , DC23 shown in FIG. 4), a signal quality sensor (such as SN21, SN22, . . . , SN23 shown in FIG. 4), and a controller CORE22. According to different designs, in some embodiments, the implementation of the control logic 250, the controller CORE21, and (or) the controller CORE22 may be hardware circuits. In some other embodiments, the implementation of the control logic 250, the controller CORE21, and (or) the controller CORE22 may be firmware. In some other embodiments, the implementation of the control logic 250, the controller CORE21, and (or) the controller CORE22 may be a combination of hardware and firmware.

In terms of hardware, the control logic 250, the controller CORE21, and (or) the controller CORE22 may be implemented in a logic circuit on an integrated circuit. For example, the related functions of the control logic 250, the controller CORE21, and (or) the controller CORE22 may be implemented as various logic blocks, modules, and circuits in one or a plurality of controllers, microcontrollers, microprocessors, application-specific integrated circuits (ASICs), digital signal processors (DSPs), field-programmable gate arrays (FPGAs), central processing units (CPUs), and/or other processing units. The related functions of the control logic 250, the controller CORE21, and (or) the controller CORE22 may be implemented as a hardware circuit, such as various logic blocks, modules, and circuits in an integrated circuit, by utilizing a hardware description language (e.g., Verilog HDL or VHDL) or other suitable programming languages.

In terms of firmware, the related functions of the control logic 250, the controller CORE21, and (or) the controller CORE22 may be implemented as programming codes. For example, the control logic 250, the controller CORE21, and (or) the controller CORE 22 are implemented by using a common programming language (e.g., C, C++, or assembly language) or other suitable programming languages. The programming code may be recorded/stored in a “non-transitory machine-readable storage medium”. In some embodiments, the non-transitory machine-readable storage medium includes, for example, a semiconductor memory and/or a storage device. An electronic equipment (such as CPU, controller, microcontroller, or microprocessor) may read and execute the programming code from the non-transitory machine-readable storage medium, so as to implement the related functions of the control logic 250, the controller CORE21, and (or) the controller CORE 22.

The interface circuit RX22 shown in FIG. 4 receives the data DRX21 to DRX23 from the die 210 via the die-to-die transfer circuit 230. The data checking circuits DC21 to DC23 are coupled to each lane of the interface circuit RX22. The data checking circuits DC21 to DC23 may check the accuracy of the data DRX21 to DRX23 from the die 210. For example, the data checking circuits DC21 to DC23 may use checksum information, error correction code (ECC), or other checking techniques of the data DRX21 to DRX23 to check the accuracy of the data DRX21 to DRX23. The controller CORE22 is coupled to the data checking circuits DC21 to DC23 to receive the checking results. The controller CORE22 feeds back the checking results regarding the accuracy of the data DRX21 to DRX23 received by the interface circuit RX22 to the control logic 250. For example, the controller CORE 22 may feed back the checking results to the control logic 250 via sideband logic that complies with the UCIe specification. Therefore, the control logic 250 may know at any time whether the data DRX21 to DRX23 received by the interface circuit RX22 are pass or fail.

The signal quality sensors SN21 to SN23 are coupled to the interface circuit RX22. The signal quality sensors SN21 to SN23 may check the signal quality of the data DRX21 to DRX23 from the die 210. The present embodiment does not limit the specific implementation of the signal quality sensors SN21 to SN23. For example, the signal quality sensors SN21 to SN23 may be conventional eye opening sensors or other signal quality sensors. The eye opening sensors may sense at least one of the eye height characteristic and the eye width characteristic of the data DRX21 to DRX23. The controller CORE22 is coupled to the signal quality sensors SN21 to SN23 to receive the sensing results. The controller CORE22 feeds back the sensing results on the signal quality of the data DRX21 to DRX23 received by the interface circuit RX22 to the control logic 250. For example, the controller CORE 22 may feed back the sensing results to the control logic 250 via sideband logic that complies with the UCIe specification. Therefore, the control logic 250 may know at any time whether the signal quality (such as at least one of the eye height characteristic and the eye width characteristic) of the data DRX21 to DRX23 received by the interface circuit RX22 meets the rated specification.

The control logic 250 may instantly collect checking results on the accuracy of the data DRX21 to DRX23 and sensing results on the signal quality of the data DRX21 to DRX23. Based on the signal quality of the data DRX21 to DRX23 received by the interface circuit RX22, the control logic 250 may control the power circuit 240 based on the signal quality of the data DRX21 to DRX23 received by the interface circuit RX22, so as to reduce the power voltage VDD as much as possible.

In the embodiment shown in FIG. 4, the die 210 includes the controller CORE21 and the interface circuit TX21. The interface circuit TX21 may transmit the data DTX21 to DTX23 to the die 220 via the die-to-die transfer circuit 230. In the initialization period of the integrated circuit device 200, the data DTX21 to DTX23 include a pseudorandom binary sequence (PRBS). The controller CORE21 is coupled to the control logic 250 and the interface circuit TX21. Based on the notification of the control logic 250, the controller CORE21 may adjust the output impedance of the output buffer (e.g., B21, B22, . . . , B23 shown in FIG. 4) of the interface circuit TX21. Based on the signal quality of the data DRX21 to DRX23 received by the interface circuit RX22, the control logic 250 may further notify the controller CORE21 to increase the output impedance of the output buffers B21 to B23 of the interface circuit TX21 based on the signal quality of the data DRX21 to DRX23 received by the interface circuit RX22. The increase in the output impedance of the output buffers B21 to B23 means that the driving capabilities of the output buffers B21 to B23 are decreased. Therefore, based on the accuracy of the data DRX21 to DRX23 received by the interface circuit RX22, and under the condition that the signal quality of the data DRX21 to DRX23 meets the rated specification, the power consumption of the output buffers B21 to B23 may be reduced as much as possible (because the driving capabilities are reduced).

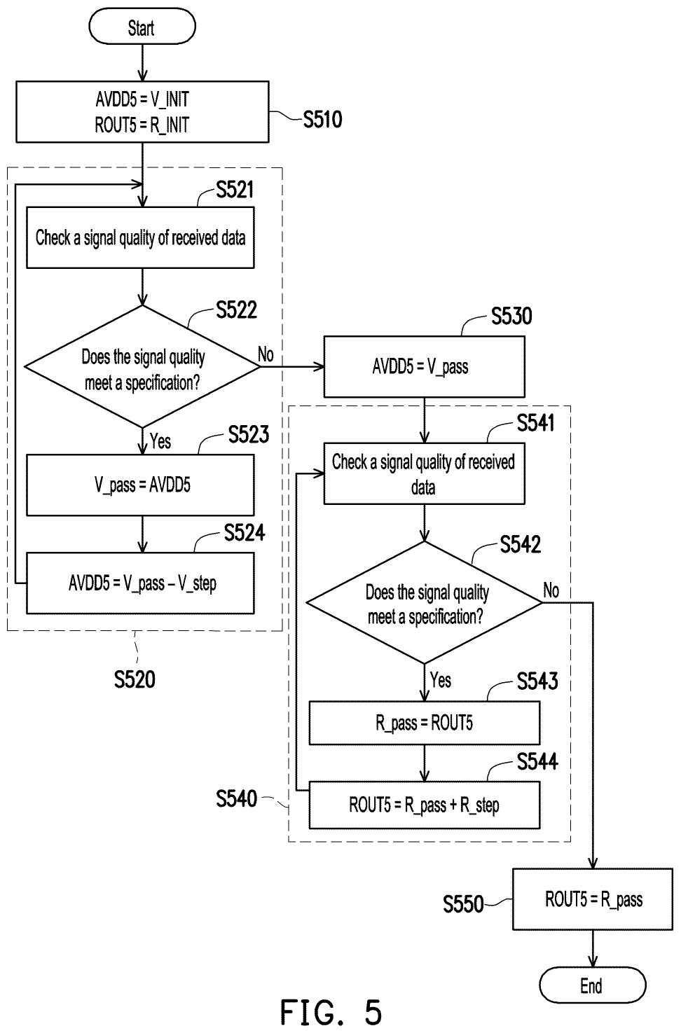

FIG. 5 is a schematic flowchart of an adaptive power scaling method according to another embodiment of the invention. Please refer to FIG. 4 and FIG. 5. In step S510, a current power voltage parameter AVDD5 is set to an initial value V_INI, and a current output impedance parameter ROUT5 is set to an initial value R_INI. The initial value V_INI and the initial value R_INI may be set according to actual design and actual application. For example, the initial value V_INI can be a voltage value that makes the signal quality of the data DRX21 to DRX23 all meet the specification, and the initial value R_INI can be an output impedance value that makes the signal quality of the data DRX21 to DRX23 all meet the specification. After completing step S510, the control logic 250 performs an operation iteration S520 of “adjusting the power voltage AVDD”.

The operation iteration S520 includes steps S521, S522, S523, and S524. In step S521, the control logic 250 may check the accuracy of the data DRX21 to DRX23 received by the interface circuit RX22 via the controller CORE22 and the data checking circuits DC21 to DC23, and check the signal quality of the data DRX21 to DRX23 via the controller CORE22 and the signal quality sensors SN21 to SN23. In response to the signal quality of the data DRX21 to DRX23 (such as at least one of the eye height feature and the eye width feature) all meeting the specification (that is, the determination result of step S522 is “yes”), the control logic 250 may copy the content of the current power voltage parameter AVDD5 to a pass power voltage parameter V_pass (step S523), and reduce the content of the current power voltage parameter AVDD5 by one step V_step (step S524). The size of the step V_step may be set according to actual design and actual application. After completing step S524, the control logic 250 may control the power circuit 240 to set the power voltage AVDD provided to the interface circuits TX21 and RX22 based on the current power voltage parameter AVDD5.

Therefore, the operation iteration S520 may reduce the power voltage AVDD as much as possible to reduce and optimize the power consumption of the integrated circuit device 200. When the signal quality of any one of the data DRX21 to DRX23 does not meet the specification (that is, the determination result of step S522 is “No”), the control logic 250 may perform step S530 to copy the content of the pass power voltage parameter V_pass to the current power voltage parameter AVDD5. After completing step S530, the control logic 250 may control the power circuit 240 to set the power voltage AVDD provided to the interface circuits TX21 and RX22 based on the current power voltage parameter AVDD5. At this point, the level of the current power voltage AVDD is an optimized low voltage under the condition of “the signal quality of the data DRX21 to DRX23 meets the rated specification”.

After completing step S530, the control logic 250 performs an operation iteration S540 of “adjusting output impedance”. The operation iteration S540 includes steps S541, S542, S543, and S544. In step S541, the control logic 250 may check the accuracy of the data DRX21 to DRX23 received by the interface circuit RX22 via the controller CORE22 and the data checking circuits DC21 to DC23, and check the signal quality of the data DRX21 to DRX23 via the controller CORE22 and the signal quality sensors SN21 to SN23. In response to the signal quality of the data DRX21 to DRX23 all meeting the specification (that is, the determination result of step S542 is “yes”), the control logic 250 may copy the content of the current output impedance parameter ROUT5 to the pass output impedance parameter R_pass (step S543), and increase the content of the current output impedance parameter ROUT5 by one step R_step (step S544). The size of the step R_step may be set according to actual design and actual application. After completing step S544, the control logic 250 may notify the controller CORE21, so that the controller CORE21 sets the output impedance of the output buffers B21 to B23 of the interface circuit TX21 based on the current output impedance parameter ROUT5.

Therefore, the operation iteration S540 may increase the output impedance of the output buffers B21 to B23 as much as possible (i.e., reduce the driving capabilities of the output buffers B21 to B23) to further reduce and optimize the power consumption of the integrated circuit device 200. When the signal quality of any one of the data DRX21 to DRX23 does not meet the specification (that is, the determination result of step S542 is “No”), the control logic 250 may perform step S550 to copy the content of the output impedance parameter R_pass to the current output impedance parameter ROUT5. After completing step S530, the control logic 250 may notify the controller CORE21 to set the output impedance of the output buffers B21 to B23 based on the current output impedance parameter ROUT5. At this point, the current output impedance of the output buffers B21 to B23 is an optimized high output impedance under the condition of “the signal quality of the data DRX21 to DRX23 meets the rated specification”.

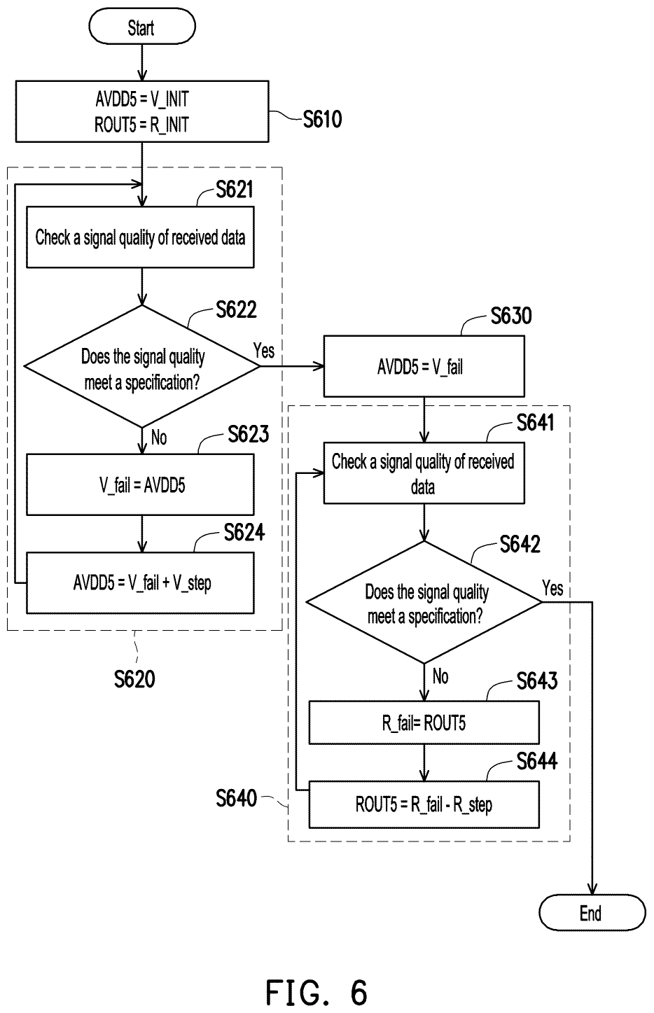

FIG. 6 is a schematic flowchart of an adaptive power scaling method according to another embodiment of the invention. Please refer to FIG. 4 and FIG. 6. In step S610, a current power voltage parameter AVDD5 is set to an initial value V_INI, and a current output impedance parameter ROUT5 is set to an initial value R_INI. The initial value V_INI and the initial value R_INI may be set according to actual design and actual application. For example, the initial value V_INI can be a voltage value that makes the signal quality of the data DRX21 to DRX23 to not meet the specification, and the initial value R_INI can be an output impedance value that makes the signal quality of the data DRX21 to DRX23 to not meet the specification. After completing step S610, the control logic 250 performs an operation iteration S620 of “adjusting the power voltage AVDD”.

The operation iteration S620 includes steps S621, S622, S623, and S624. In step S621, the control logic 250 may check the accuracy of the data DRX21 to DRX23 received by the interface circuit RX22 via the controller CORE22 and the data checking circuits DC21 to DC23, and check the signal quality of the data DRX21 to DRX23 via the controller CORE22 and the signal quality sensors SN21 to SN23. In response to the signal quality of any one of the data DRX21 to DRX23 not meet the specification (that is, the determination result of step S622 is “No”), the control logic 250 may copy the content of the current power voltage parameter AVDD5 to a fail power voltage parameter V_fail (step S623), and increase the content of the current power voltage parameter AVDD5 by one step V_step (step S624). The size of the step V_step may be set according to actual design and actual application. After completing step S624, the control logic 250 may control the power circuit 240 to set the power voltage AVDD provided to the interface circuits TX21 and RX22 based on the current power voltage parameter AVDD5.

In response to the signal quality of the data DRX21 to DRX23 (such as at least one of the eye height feature and the eye width feature) all meeting the specification (that is, the determination result of step S622 is “yes”), the control logic 250 may perform step S630 to copy the content of the fail power voltage parameter V_fail to the current power voltage parameter AVDD5. After completing step S630, the control logic 250 may control the power circuit 240 to set the power voltage AVDD provided to the interface circuits TX21 and RX22 based on the current power voltage parameter AVDD5. After completing step S630, the control logic 250 performs an operation iteration S640 of “adjusting output impedance”.

The operation iteration S640 includes steps S641, S642, S643, and S644. In step S641, the control logic 250 may check the accuracy of the data DRX21 to DRX23 received by the interface circuit RX22 via the controller CORE22 and the data checking circuits DC21 to DC23, and check the signal quality of the data DRX21 to DRX23 via the controller CORE22 and the signal quality sensors SN21 to SN23. In response to the signal quality of any one of the data DRX21 to DRX23 not meet the specification (that is, the determination result of step S642 is “No”), the control logic 250 may copy the content of the current output impedance parameter ROUT5 to the fail output impedance parameter R_fail (step S643), and reduce the content of the current output impedance parameter ROUT5 by one step R_step (step S644). The size of the step R_step may be set according to actual design and actual application. After completing step S644, the control logic 250 may notify the controller CORE21, so that the controller CORE21 sets the output impedance of the output buffers B21 to B23 of the interface circuit TX21 based on the current output impedance parameter ROUT5.

In response to the signal quality of the data DRX21 to DRX23 all meeting the specification (that is, the determination result of step S642 is “yes”), the current output impedance of the output buffers B21 to B23 is an optimized high output impedance under the condition of “the signal quality of the data DRX21 to DRX23 meets the rated specification”. At this point, the optimized low voltage of the supply voltage AVDD can be found, and the operation iteration S640 may increase the output impedance of the output buffers B21 to B23 as much as possible (i.e., reduce the driving capabilities of the output buffers B21 to B23).

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. An integrated circuit device comprising a first die and a second die, wherein the first die and the second die are stacked into a three-dimensional structure, and the integrated circuit device further comprises:
a power circuit for providing a power voltage to a first interface circuit of the first die and a second interface circuit of the second die, wherein the first interface circuit transmits data to the second interface circuit via an die-to-die transfer circuit of the integrated circuit device; and
a control logic coupled to the power circuit, wherein the second die reports an signal quality of the received data to the control logic, and the control logic controls the power circuit to adjust the power voltage provided to the first interface circuit and the second interface circuit based on the signal quality of the data received by the second interface circuit.

2. The integrated circuit device of claim 1, wherein in an initialization period of the integrated circuit device, the data comprises a pseudo-random binary sequence.

3. The integrated circuit device of claim 1, wherein the power circuit comprises a voltage regulator or a DC-DC converter.

4. The integrated circuit device of claim 1, wherein the control logic controls the power circuit to adjust the power voltage based on a signal quality of the data received by the second interface circuit.

5. The integrated circuit device of claim 4, wherein the signal quality comprises at least one of an eye height characteristic and an eye width characteristic of the data.

6. The integrated circuit device of claim 1, wherein the second die comprises:
the second interface circuit, wherein the second interface circuit receives the data from the first die via the die-to-die transfer circuit;
a second controller; and
at least one signal quality sensor coupled to the second interface circuit, wherein the at least one signal quality sensor checks a signal quality of the data received from the first die, the second controller is coupled to the at least one signal quality sensor to receive a sensing result, and the second controller feeds back the sensing result regarding the signal quality of the data received by the second interface circuit to the control logic,
wherein the control logic controls the power circuit to adjust the power voltage based on the signal quality of the data received by the second interface circuit.

7. The integrated circuit device of claim 6, wherein the second controller feeds back the checking result and the sensing result to the control logic via a sideband logic.

8. The integrated circuit device of claim 6, wherein an operation of adjusting the power voltage comprises the following iteration:
checking the signal quality of the data received by the second interface circuit; and
copying a content of a current power voltage parameter to a pass power voltage parameter, reducing the content of the current power voltage parameter by one step, and controlling the power circuit to set the power voltage provided to the first interface circuit and the second interface circuit based on the current power voltage parameter in response to the signal quality of the data received by the second interface circuit meeting a specification.

9. The integrated circuit device of claim 6, wherein an operation of adjusting the power voltage comprises the following iteration:
checking the signal quality of the data received by the second interface circuit; and
copying a content of a current power voltage parameter to a fail power voltage parameter, increasing the content of the current power voltage parameter by one step, and controlling the power circuit to set the power voltage provided to the first interface circuit and the second interface circuit based on the current power voltage parameter in response to the signal quality of the data received by the second interface circuit not meeting the specification.

10. The integrated circuit device of claim 6, wherein the first die comprises:
the first interface circuit, wherein the first interface circuit transmits the data to the second die via the die-to-die transfer circuit; and
a first controller coupled to the control logic and the first interface circuit, wherein the first controller adjusts an output impedance of at least one output buffer of the first interface circuit based on a notification of the control logic.

11. The integrated circuit device of claim 10, wherein the control logic notifies the first controller to adjust the output impedance of the at least one output buffer of the first interface circuit based on the signal quality of the data received by the second interface circuit.

12. The integrated circuit device of claim 11, wherein an operation of adjusting the output impedance comprises the following iteration:
checking the signal quality of the data received by the second interface circuit; and
copying a content of a current output impedance parameter to a pass output impedance parameter, increasing the content of the current output impedance parameter by one step, and setting the output impedance of the at least one output buffer of the first interface circuit via the first controller based on the current output impedance parameter in response to the signal quality of the data received by the second interface circuit meeting a specification.

13. The integrated circuit device of claim 11, wherein an operation of adjusting the output impedance comprises the following iteration:
checking the signal quality of the data received by the second interface circuit; and
copying a content of a current output impedance parameter to a fail output impedance parameter, reducing the content of the current output impedance parameter by one step, and setting the output impedance of the at least one output buffer of the first interface circuit via the first controller based on the current output impedance parameter in response to the signal quality of the data received by the second interface circuit not meeting the specification.

14. An adaptive power scaling method of an integrated circuit device, wherein the integrated circuit device comprises a first die and a second die, the first die and the second die are stacked into a three-dimensional structure, and the adaptive power scaling method comprises:
providing a power voltage to a first interface circuit of the first die and a second interface circuit of the second die by a power circuit of the integrated circuit device, wherein the first interface circuit transmits data to the second interface circuit via a die-to-die transfer circuit of the integrated circuit device;
reporting a signal quality of the received data to a control logic of the integrated circuit device by the second die; and
controlling the power circuit by the control logic to adjust the power voltage provided to the first interface circuit and the second interface circuit based on the signal quality of the data received by the second interface circuit.

15. The adaptive power scaling method of claim 14, wherein in an initialization period of the integrated circuit device, the data comprises a pseudo-random binary sequence.

16. The adaptive power scaling method of claim 14, wherein the power circuit comprises a voltage regulator or a DC-DC converter.

17. The adaptive power scaling method of claim 14, further comprising:
adjusting the power voltage based on a signal quality of the data received by the second interface circuit.

18. The adaptive power scaling method of claim 17, wherein the signal quality comprises at least one of an eye height characteristic and an eye width characteristic of the data.

19. The adaptive power scaling method of claim 14, further comprising:
checking a signal quality of the data received from the first die by at least one signal quality sensor of the second die;
feeding back a sensing result regarding the signal quality of the data received by the second interface circuit to the control logic by a second controller of the second die; and
controlling the power circuit by the control logic to adjust the power voltage based on the signal quality of the data received by the second interface circuit.

20. The adaptive power scaling method of claim 19, wherein the second controller feeds back the checking result and the sensing result to the control logic via a sideband logic.

21. The adaptive power scaling method of claim 19, wherein an operation of adjusting the power voltage comprises the following iteration:
checking the signal quality of the data received by the second interface circuit; and
copying a content of a current power voltage parameter to a pass power voltage parameter, reducing the content of the current power voltage parameter by one step, and controlling the power circuit to set the power voltage provided to the first interface circuit and the second interface circuit based on the current power voltage parameter in response to the signal quality of the data received by the second interface circuit meeting a specification.

22. The adaptive power scaling method of claim 19, wherein an operation of adjusting the power voltage comprises the following iteration:
checking the signal quality of the data received by the second interface circuit; and
copying a content of a current power voltage parameter to a fail power voltage parameter, increasing the content of the current power voltage parameter by one step, and controlling the power circuit to set the power voltage provided to the first interface circuit and the second interface circuit based on the current power voltage parameter in response to the signal quality of the data received by the second interface circuit not meeting the specification.

23. The adaptive power scaling method of claim 19, further comprising:
adjusting an output impedance of at least one output buffer of the first interface circuit by a first controller of the first die based on a notification of the control logic.

24. The adaptive power scaling method of claim 23, further comprising:
notifying the first controller by the control logic to adjust the output impedance of the at least one output buffer of the first interface circuit based on the signal quality of the data received by the second interface circuit.

25. The adaptive power scaling method of claim 24, wherein an operation of adjusting the output impedance comprises the following iteration:
checking the signal quality of the data received by the second interface circuit; and
copying a content of a current output impedance parameter to a pass output impedance parameter, increasing the content of the current output impedance parameter by one step, and setting the output impedance of the at least one output buffer of the first interface circuit via the first controller based on the current output impedance parameter in response to the signal quality of the data received by the second interface circuit meeting a specification.

26. The adaptive power scaling method of claim 24, wherein an operation of adjusting the output impedance comprises the following iteration:
checking the signal quality of the data received by the second interface circuit; and
copying a content of a current output impedance parameter to a fail output impedance parameter, reducing the content of the current output impedance parameter by one step, and setting the output impedance of the at least one output buffer of the first interface circuit via the first controller based on the current output impedance parameter in response to the signal quality of the data received by the second interface circuit not meeting the specification.
